(19) United States
(12) Patent Application Publication
(10) Pub. No.: US 2011/0188201 A1
(43) Pub. Date: Aug. 4, 2011

(54) ELECTRONIC DEVICE WITH VIBRATION-ABSORBING FUNCTION

(75) Inventor: SHENG-HAN LIN, Tu-Cheng (TW)

(73) Assignee: HON HAI PRECISION INDUSTRY CO., LTD., Tu-Cheng (TW)

(21) Appl. No.: 12/780,955

(22) Filed: May 17, 2010

(30) Foreign Application Priority Data
Feb. 3, 2010 (TW) 99103260

(51) Int. Cl. H05K 7/20; G06F 1/16

(52) U.S. Cl. 361/695; 361/688; 361/679.34

(57) ABSTRACT

An electronic device includes a base, a cover covering on the base, and a cooling assembly mounted between the base and the cover. A vibration-absorbing pad is sandwiched between a bottom of the cooling assembly and the base, and a vibration-absorbing block is sandwiched between a top of the cooling assembly and the cover.

### BACKGROUND

1. Technical Field

The present disclosure relates to electronic devices, and more particularly to an electronic device with vibration absorbing function.

2. Description of Related Art

Commonly, an electronic device, such as a computer, includes a cooling assembly with several blowers, to dissipate heat for a power supply within the electronic device. The cooling assembly is often mounted to a housing of the electronic device, and generates vibration along with heat dissipation. The vibration may be transferred to storage units of the electronic device via the housing of the electronic device, which may cause read and write errors to the storage units.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an exploded, isometric view of an exemplary embodiment of an electronic device, the electronic device includes two blowers.

FIG. 2 is an inverted view of the blowers of FIG. 1.

FIG. 3 is a partially assembled view of the electronic device of FIG. 1.

FIG. 4 is an assembled, isometric view of the electronic device of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

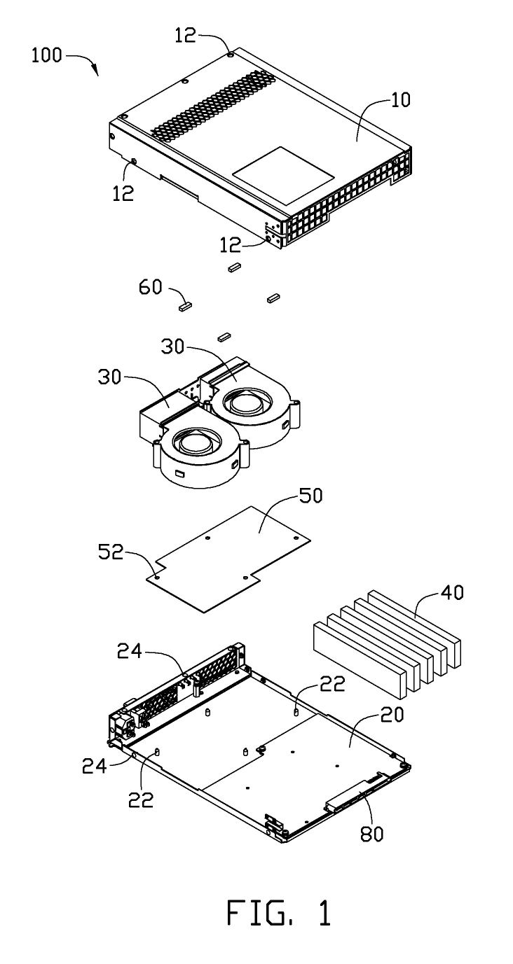

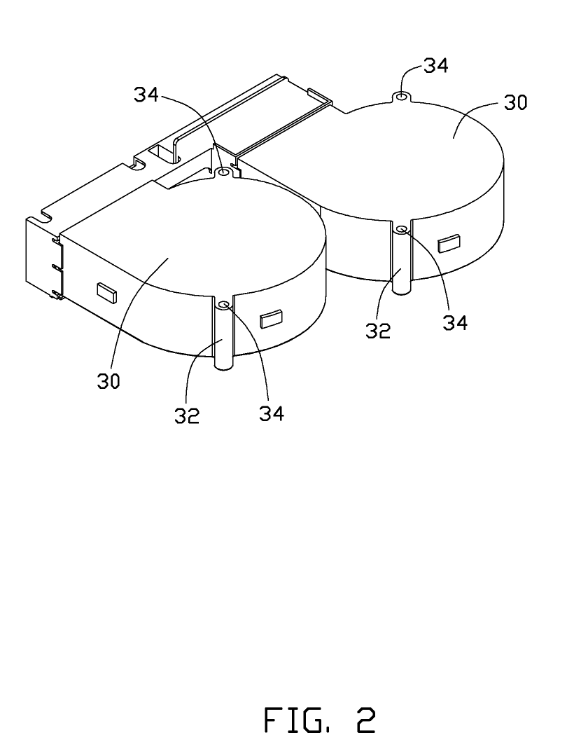

Referring to FIGS. 1 and 2, an exemplary embodiment of an electronic device 100 includes a rectangular cover 10, a rectangular base 20, a cooling assembly, several storage units, a rectangular vibration-absorbing pad 50, and four vibration-absorbing blocks 60. In one embodiment, the cooling assembly includes two blowers 30 and the storage units are five hard disk drives 40.

Several through holes 12 are defined adjacent to edges of the cover 10.

The base 20 defines several screw holes 24 corresponding to the through holes 12. Four pins 22 extend up from the base 20. The base 20 includes several interfaces 80, to connect to other electronic devices (not shown).

Each of the blowers 30 includes two opposite columns 32 extending from a circumference of the blower 30. A fixing hole 34 is axially defined in each of the convex columns 32, corresponding to the pins 22 of the base 20.

The vibration-absorbing pad 50 is made of vibration absorbing material, such as rubber, foam, or combination of both, and defines four through holes 52 corresponding to the pins 22 of base 20.

The vibration-absorbing blocks 60 are made of vibration absorbing material, such as foam, rubber or combination of both.

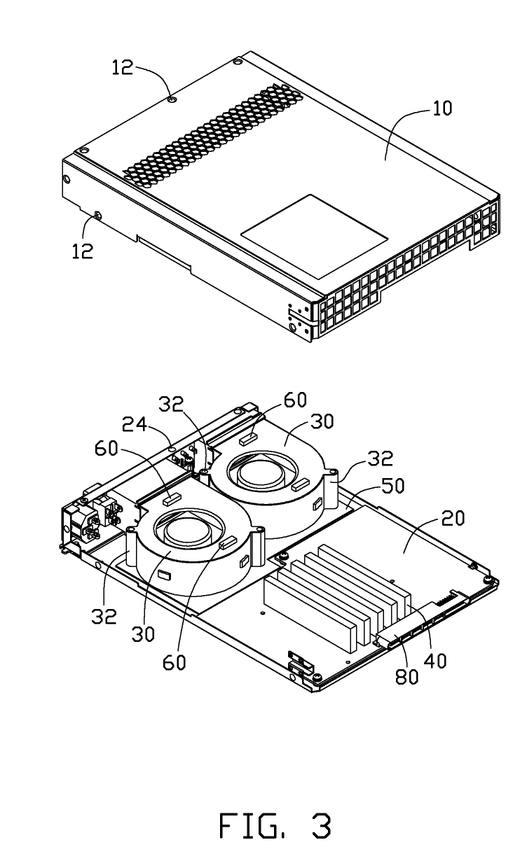

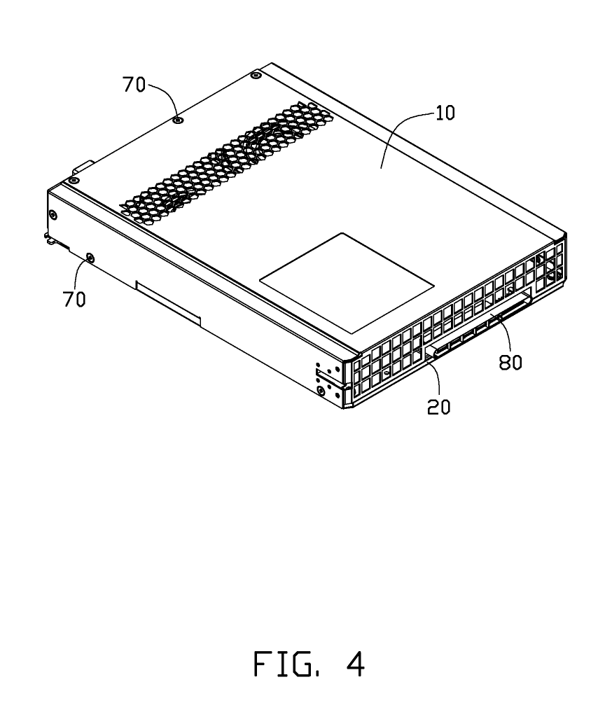

Referring to FIGS. 3 and 4, in assembly, the pins 22 of the base 20 extend through the corresponding through holes 52 of the absorbing pad 50 and engage in the fixing holes 34 of the blowers 30, to mount the blowers 30 to the base 20 and sandwich the vibration-absorbing pad 50 between the bottoms of the blowers 30 and the base 20. The hard disk drives 40 are mounted to the base 20 by several fixing members, such as screws (not shown), beside the vibration-absorbing pad 50, and electrically connected to the interface 80 via a circuit board (not shown). The vibration-absorbing blocks 60 are stuck to the tops of the blowers 30. The cover 10 is assembled to the base 20 by extension of several screws through the through holes 12 of the cover 10 and engaging in the screw holes 24 of the base 20. The vibration-absorbing blocks 60 are sandwiched between the tops of the blowers 30 and the cover 10.

When the electronic device 100 powers on, the blowers 30 dissipate heat for a power supply (not shown) of the electronic device 10 and generate vibration. The vibration-absorbing pad 50 and the vibration-absorbing blocks 60 absorb vibrations to prevent vibrations from being transferred to the hard disk drives 40. The vibration-absorbing pad 50 and the vibration-absorbing blocks 60 also absorb noise generated by the blowers 30.

In other embodiments, the hard disk drives 40 may be set outside of the cover 10 and the base 20 and are connected to the interfaces 80 of the electronic device 100 by a circuit board. Shapes and placements of the vibration-absorbing pad 50 and the vibration-absorbing blocks 60 may be regulated according to needs. The blowers 30 may be replaced with other types of cooling assemblies, such as fans.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An electronic device, comprising:
a base;
a cover covering on the base;
a cooling assembly mounted on the base and located between the base and the cover;
a vibration-absorbing pad sandwiched between the base and a bottom of the cooling assembly; and
at least one vibration-absorbing block sandwiched between the cover and a top of the cooling assembly.

2. The electronic device of claim 1, further comprising at least one storage unit mounted on the base beside the vibration-absorbing pad.

3. The electronic device of claim 2, wherein the cooling assembly includes at least one blower, wherein a plurality of fixing holes is defined in the blower, a plurality of pins extends from the base engaged in the plurality of fixing holes to fasten the at least one blower on the base.

4. The electronic device of claim 3, wherein at least two columns extend from a circumference of each of the at least one blower, the plurality of fixing holes is axially defined in the columns.

5. The electronic device of claim 3, wherein the vibration-absorbing pad is made of vibration absorbing material, a plurality of through holes are defined in the vibration-absorbing pad, the plurality of pins of the base extends through the plurality of through holes of the vibration-absorbing pad to engage with the bottom of the at least one blower.

6. The electronic device of claim 3, wherein the at least one vibration-absorbing block comprises four vibration-absorbing blocks, the vibration-absorbing blocks are made of vibration absorbing material and are stuck to the top of the at least one blower.

7. The electronic device of claim 1, wherein the at least one vibration-absorbing block is made of vibration absorbing material and is mounted to the top of the cooling assembly.

8. The electronic device of claim 7, wherein the at least one vibration-absorbing block is made of rubber.

9. The electronic device of claim 1, wherein the vibration-absorbing pad is made of foam, rubber, or combination of both.
